(19) United States
(12) Patent Application Publication
(10) Pub. No.: US 2024/0021557 A1
(43) Pub. Date: Jan. 18, 2024

(54) SEMICONDUCTOR DEVICE AND BUMP ARRANGEMENT METHOD

(71) Applicant: RENESAS ELECTRONICS CORPORATION, Tokyo (JP)

(72) Inventor: Kazuo SAKAMOTO, Tokyo (JP)

(21) Appl. No.: 17/864,038

(22) Filed: Jul. 13, 2022

(51) Int. Cl. H01L 23/00; H01L 21/56

(52) U.S. Cl. CPC H01L 24/17; H01L 24/16; H01L 24/32; H01L 24/73; H01L 24/83; H01L 24/81; H01L 21/563; H01L 2924/35121; H01L 2924/381; H01L 2224/81911; H01L 2224/83911; H01L 2224/17132; H01L 2224/16225; H01L 2224/32225; H01L 2224/73204; H01L 2224/17133

(57) ABSTRACT

This invention provides a placement area with an enlarged bump pitch while avoiding the risk of underfill void generation in the bump process.

The number of bumps is not changed, but the bump pitch at the center is arranged in parallel with the drying direction of the flip-chip process in the drying direction, and an arrangement area in which n rows are enlarged by +b(μm) bump pitch is made, and the chip area is finely adjusted.

According to the invention, with respect to the dry air direction after flux cleaning, the power of the dry air does not change for creating a minute bump enlarged area parallel to the air in the central portion.

### BACKGROUND

The present invention relates to a bump arrangement method of the semiconductor device in the flip-chip connection.

### THE BACKGROUND OF THE INVENTION

One method of mounting a semiconductor element on a package substrate having a patterned conductive layer is flip mounting method. By such a flip-chip mounting method, in the case of mounting the semiconductor element, placing a protruding electrode called a bump in the semiconductor element, toward the surface comprising a bump to the package substrate, the conductor layer of the bump and the substrate is mounted so as to be electrically connected directly or via a conductive material. For example, a plurality of bumps 2 are arranged in the semiconductor chip 1 in FIG. 1, various elements via the bumps 2 (the corner portion of the package substrate 1, a plurality of analog macros 3, a plurality of I/O areas 4 and a plurality of DDRIO+macros 5, various modules 6 inside the semiconductor chip 1) are connected.

There are disclosed techniques listed below.
[Patent Document 1] Japanese Unexamined Patent Application Publication No. 1993-062978
[Patent Document 2] Japanese Unexamined Patent Application Publication No. 2014-179433
[Patent Document 3] Japanese Unexamined Patent Application Publication No. 2001-345347
[Patent Document 4] Japanese Unexamined Patent Application Publication No. 2000-260792
[Non Patent Document 1] Ohno Yuji and five others, “Impact of area array type flip-chip compatible with lead-free on reliability through use of fine pitch”, MES2011, September 2011, p. 169-172

Patent Document 1 relates to a flip-chip, without breaking the conventional plurality of pad layout rules, and aims to improve the productivity while improving the function as a semiconductor chip by increasing the arrangement density of the pads or bumps. For this purpose, all of the signal input and output terminal pads are collected on one side of the semiconductor chip, and a flip chip in which the pads are formed in a bump of the same shape, the respective bumps forming a plurality of circular shape, the technique of configuring arranged in a staggered grid shape of equal pitch is disclosed.

Patent Document 2 discloses a technique for improving the bump density of the micro bumps in the semiconductor device, specifically, comprising a plurality of micro bumps arranged in a staggered grid in a bump area disposed on one surface of the semiconductor chip, for a plurality of bump rows in which a plurality of micro bumps are arranged, the pitch between adjacent bump rows, the same bump row. It is arranged so as to differ the pitch between adjacent micro bumps arranged.

Patent Document 3 discloses a technique relating to a connection structure and pin arrangement that can be resin-sealed at a predetermined pitch and can be mounted in an area arrangement. Features of the present technique, when cut in a cross section passing through the center of the connecting portion which is an area array, the cross-sectional area of one connecting portion S1, the cross-sectional area of the gap between adjacent connecting portions S2, N1 the number of longitudinal connecting portions, and N2 the number of lateral connecting portions, even if S1 is equal to or larger than S2, N2/N1 equal to or larger than S1/S2, it is to encapsulate the resin from the side where the lateral connecting portion is present.

Patent Document 4 discloses a flip-chip type semiconductor device, which has a high reliability of the connecting portion, and is capable of terminating the filling of the resin material for underfill formation in a short time. Specifically, the chip on one side of the wiring board is mounted on the face-down, is electrically connected via a solder bump, the average gap height between the chip and the wiring board is calculated from the variation amount of the arrangement pitch and the gap height of the bump characterized in that it is set at a value.

On the other hand, Non-Patent Document 1, which has been used in many applications, the area array flip-chip bonding technique known as C4 (Controlled Collapse Chip Connection) is disclosed, the bump pitch of the flip-chip is the content of investigating the reliability performance against thermal cyclic stresses by becoming increasingly fine, using different underfill resin It has been reported in the experimental study of the array flip-chip.

### SUMMARY

In Patent Documents 1 and 2, it is possible to reduce the chip size by arranging the bumps in a staggered grid shape at a minimum pitch, and realizes multi functionalization by increasing the number of bumps. In Patent Document 3, although different grid-shaped bump arrangement of vertical and horizontal dimensions are disclosed, minimizing the bump pitch in the uniform pitch of the number of bumps and bumps. In Patent Document 4, the bump size, but defines the relationship between the bump pitch and the chip-package substrate height, the bump pitch assumes a uniform pitch.

In the product development of a general semiconductor device, in the initial stage, as in the techniques disclosed in Patent Documents 1 and 2, and the area estimated size of the inner area of the semiconductor chip, the bump at the minimum pitch staggered grid It has determined the chip area by a method of arranging the.

However, at the end of the product development, due to requirements such as performance improvement, the size of some modules disposed inside the semiconductor chip (e.g., module (B)) in FIG. 1 may be increased. As a countermeasure of such module size enlargement, as shown in FIG. 2, while maintaining the minimum bump pitch without changing the number of bumps, I/O area 4 which does not affect the characteristics of the product (e.g., I/O area 1) by shifting to the chip corner side for adjustment of the chip size.

On the other hand, areas such as analog macro-3 and DDRI/O+macro-5, which affect the characteristics of the product, cannot be shifted toward the chip corner, resulting in dead-space 7 and low mounting areas that cannot be effectively used. Also for the I/O area 4 shifted to the chip corner side, it was necessary to redesign the connection between the bump terminal and I/O cell terminals or to re-extract the actual load for characterization.

On the other hand, as a bonding method of the package substrate and the flip-chip, cleaning the flux between the chip and the package substrate after solder bonding, a method of injecting a sealing resin (underfill) between the chip and the package substrate is known. As disclosed in Non-Patent Document 1, in the process step of the flip-chip bonding, the underfill void is generated when the discontinuous portion is present in the bump arrangement, there is a problem that the junction of the void generating portion is peeled off during use environment is reduced.

In particular, flux cleaning, rinsing and drying between the chip and the package substrate after solder bonding, in a method of injecting a sealing resin (underfill) between the chip and the package substrate, as a drying process, hot air drying method has been selected from the viewpoint of production cost and throughput. In this drying process, when the discontinuous portion of the bump pitch is on the leeward side of the dry air, the pressure of the dry air decreases, especially around the bump on the outlet side of the dry air is not sufficiently dried, there was a case where the water mark is generated. When the water mark is generated, the adhesion of the watermark portion in the subsequent sealing resin (underfill) injection process will be reduced, the phenomenon of peeling in the actual use environment has been known.

Other objects and novel features will become apparent from the description of this specification and the accompanying drawings.

According to an embodiment, the semiconductor device, without changing the number of bumps, parallel to the drying air direction at the time of drying the bump pitch of the central portion of the package substrate in the flip-chip process, and so as to create an arrangement area bump pitch enlarged by a predetermined size. This made it possible to fine-tune the chip area. In addition, there is no need to change the layout relationship between the bumps for I/O areas and analog macros in the package substrate and the I/O areas and analog macros.

According to the one embodiment, with respect to the dry air direction after flux cleaning, the central portion of the package substrate, to create a minute bump enlarged area parallel to the dry air, the pressure of the dry air does not change. Therefore, it is possible to avoid the risk of underfill voids occurring in the bump process.

### BRIEF DESCRIPTION OF THE DRAWINGS

FIG. 1 is a diagram for explaining an area adjustment method according to the prior art.

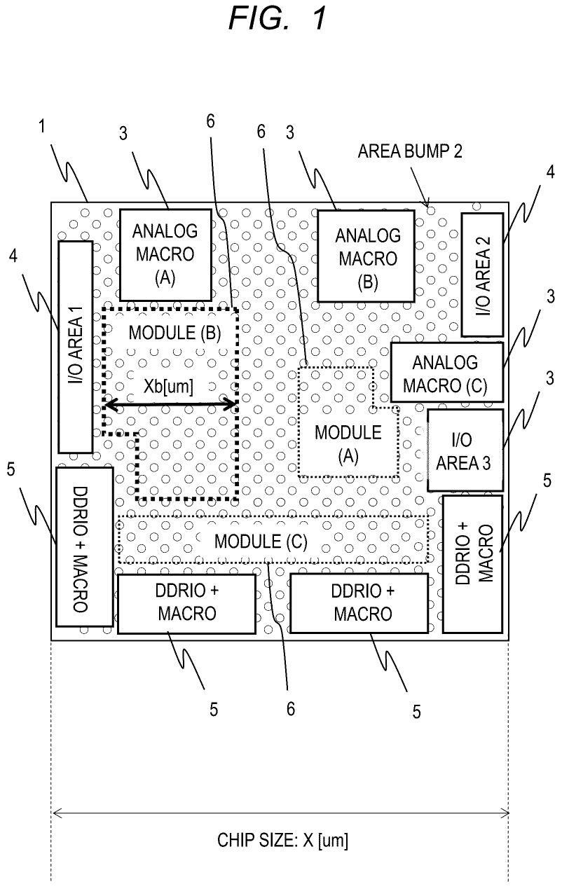

FIG. 2 is a diagram for explaining the problems of the area adjustment method according to the prior art.

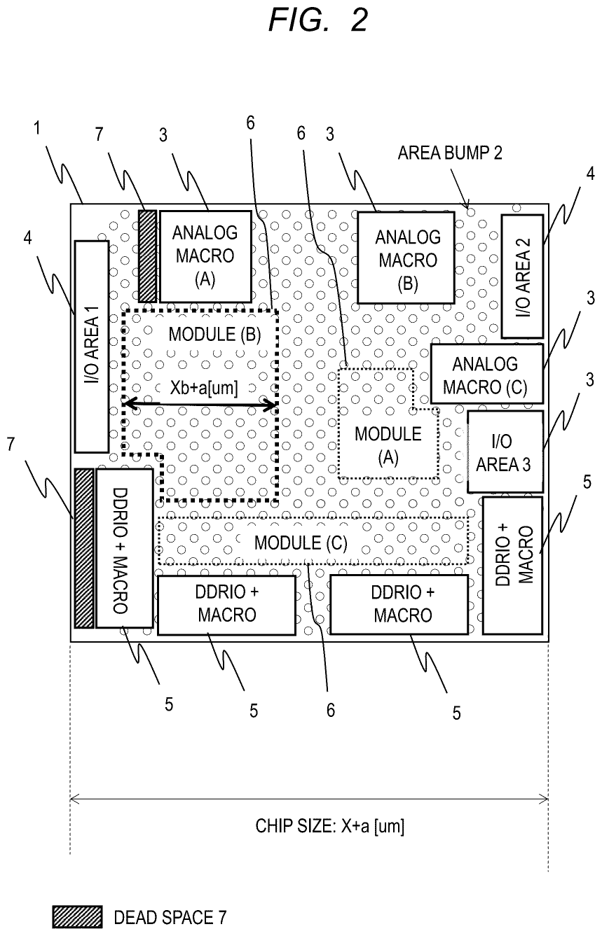

FIG. 3 is a diagram for explaining an area adjustment method according to the first embodiment.

FIG. 4 is a bump arrangement enlargement flow according to the first embodiment.

FIG. 5 is a diagram showing an example of bump arrangement before the area adjustment according to the first embodiment.

FIG. 6 is a diagram showing an example of bump arrangement after the area adjustment according to the first embodiment.

FIG. 7 is a diagram for explaining an area adjustment method according to the second embodiment.

FIG. 8 is a diagram for explaining an area adjustment method according to the third embodiment.

FIG. 9 is a diagram showing a bump coordinate calculation method with a specific side as the left side.

### DETAILED DESCRIPTION

Hereinafter, a data processing device according to an embodiment will be described in detail by referring to the drawings. In the specification and the drawings, the same or corresponding form elements are denoted by the same reference numerals, and a repetitive description thereof is omitted. In the drawings, for convenience of description, the configuration may be omitted or simplified. Also, at least some of the embodiments may be arbitrarily combined with each other.

### First Embodiment

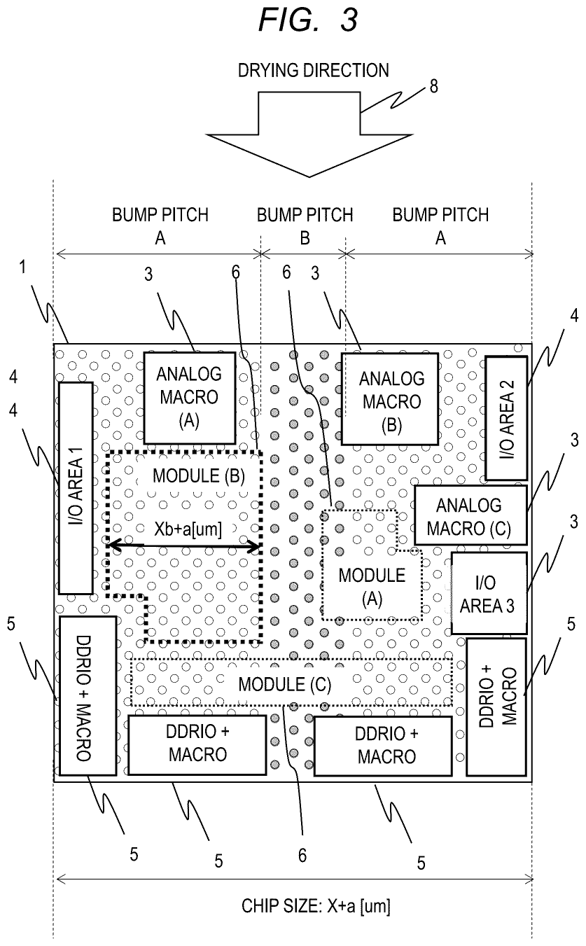

FIG. 3 is a diagram showing an arrangement example of the semiconductor chip 1 after performing the bump arrangement enlargement in the first embodiment. Semiconductor chip 1 before enlargement, the size X(μm) in the X direction, the bump pitch area is a uniform bump pitch, the case of expanding a 1 (μm) the semiconductor chip 1 in the X direction will be described. Without changing the number of bumps, the bump pitch B area having an enlarged bump pitch with respect to the drying air direction 8 during drying of the flip-chip process is provided in the central portion. In the bump pitch B area, the bump pitch is enlarged by b(μm) for n rows of bumps, thereby finely adjusting the chip area. Incidentally, the bump pitch of the area and the I/O area where the analog macro 3 is disposed is not changed, also it is assumed that the respective arrangement relationship is not changed.

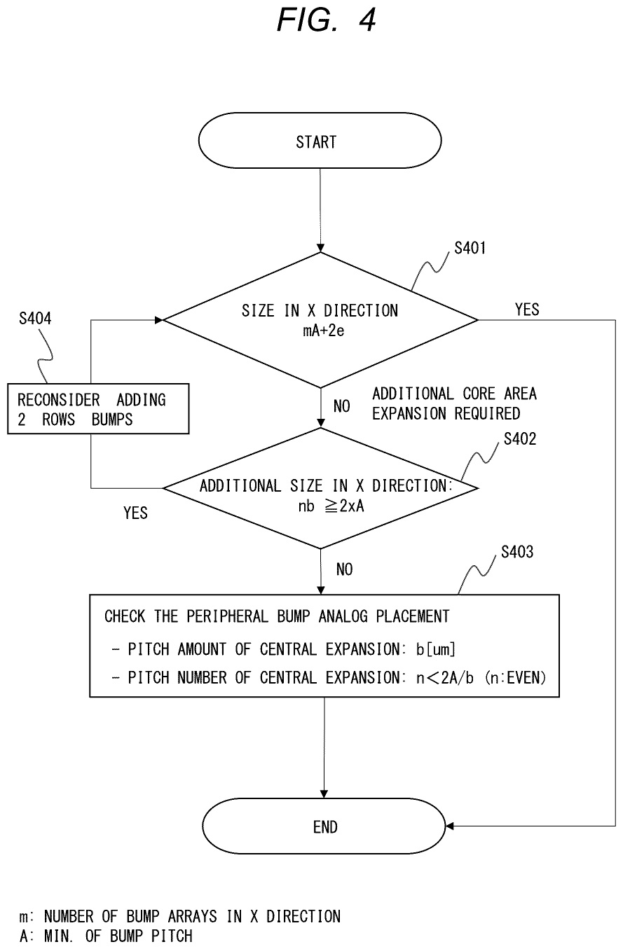

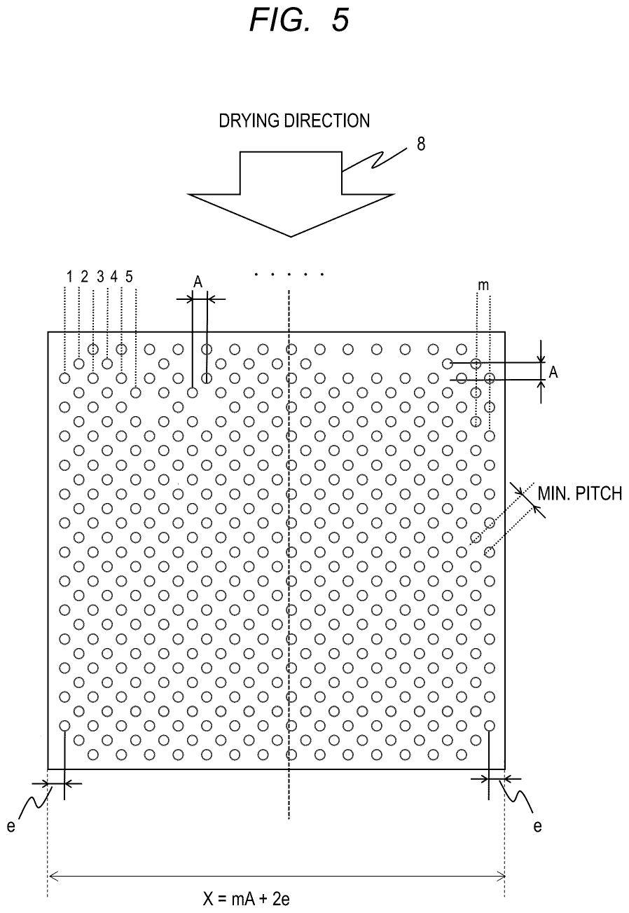

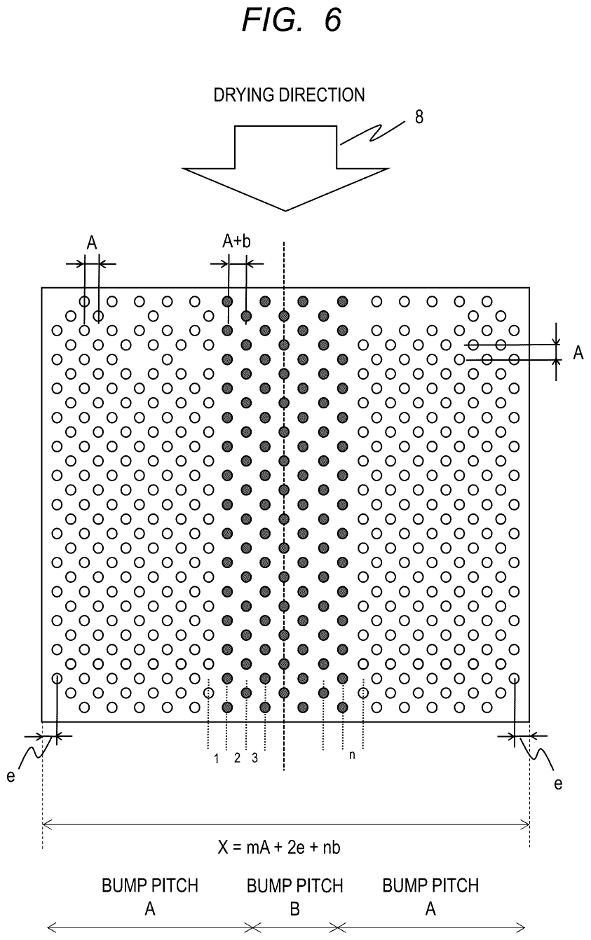

The bump arrangement enlargement flow according to the first embodiment is shown in FIG. 4, an example of the bump arrangement before the bump arrangement enlargement is shown in FIG. 5, and an example of the arrangement after the bump arrangement enlargement is shown in FIG. 6, respectively.

As shown in FIG. 5, in the early stage of development, first, the bump pitch is arranged in a staggered grid at the minimum pitch according to the bump pitch rule in the bump process rule. For example, for a 130 (μm) bump pitch rule, the bump arrangement A in the X and Y directions may be 92 (μm) (bump pitch rule=staggered grid bump pitch*\sqrt{2}). The space e between the bump and the chip boundary is also determined by the process rules. During the initial stage of development, the chip size and the number of bumps are determined from the relationship between the area estimation of the circuit scale disposed inside the semiconductor chip and the smallest bump pitch. In the first embodiment, the number of bump arrays m in the X direction, the smallest bump pitch A, from the space e of the bump and the chip boundary, the X direction size of the semiconductor chip becomes mA+2e. The size in the Y direction can also be calculated in the same way as the X direction.

Further, if an area affecting the characteristics in the analog macro 3 (e.g., transceiver circuit for transmitting and receiving a signal at high speed) or an element formed by a bump layer (e.g., a coil or an inductor, often formed of an aluminum layer used in the bump) is mounted, the bump omission occurs in the analog macro 3 may be occurred. The macro side with different pitch bumps is placed at the inlet of the dry air direction so that the pressure of the dry air after flux cleaning does not change.

After that, as the development progresses, the area adjustment of the module inside the package substrate may be required due to the requirements for further speed-up and additional function of the system. As a result of the area trial calculation again, when it is decided to adjust the area while maintaining the number of bumps, as shown in FIG. 6, the area is expanded by providing the area of the n-rows*b(μm) pitch in the chip central portion. The enlarged area is arranged so as to be parallel to the dry air direction after flux cleaning. Incidentally, b(μm) for enlargement is also determined by the bump process rule.

When expanding the area, if a bump pitch B area is created in the center of the chip in the direction perpendicular to the drying air direction, or if a bump pitch area with 2A pitch or more is locally created, the pressure of the drying air changes and it causes underfill voids.

When the bump pitch B area of n rows is created, the chip size in the X direction becomes mA+2e+nb. (To maintain the bump count, nb<2A.) For example, if a bump pitch B area of eight rows is created at b=23 (μm), the size is enlarged by 184 (μm) for the size mA+2e in the X direction at the initial stage of development. If nb exceeds 2A, it is desirable to review the chip size after the addition of two rows of bumps.

According to the bump arrangement enlargement flow as shown in FIG. 4, a method for estimating the chip size will be described.

When starting to estimate the chip size, first check whether the size in the X direction is “mA+2e (m: number of bump arrays in the X direction, A: minimum bump pitch)” (step S401). As a result of the check, if YES, the estimate is completed and the chip size is determined. On the other hand, if NO, an additional expansion of the core area is required, and then it is checked whether the additional size quantity in the X direction is “nb≥2×A (n: number of additional bump arrays in the X direction, b: enlarged bump pitch)” (step S402). As a result of the check, if YES, it is reexamined to add two rows of bumps (step S404), and the result of the reexamination is checked (return to the step S401). On the other hand, if NO, the analog arrangement of the peripheral bumps is checked (S403 of steps). In this case, the enlarged pitch amount of the central portion: b(μm), the center portion enlarged pitch number: n<2A/b (n: even number). As a result of such confirmation, the estimation is completed and the chip size is determined.

(Effect of the First Embodiment)

According to the bump pitch arrangement method in the first embodiment,
(1) When performing adjustment of the area, it is not necessary to move the sensitive I/O area or analog macro of the characteristics disposed in the bump pitch area A, low mounting area that can not be used effectively dead space or area does not occur.
(2) As shown in FIG. 3, it is possible to maintain the relationship between the I/O arrangement and the bump by area countermeasures at the bump pitch enlarge in the central portion, and the AC characteristics and ESD breakdown voltage with area expansion do not deteriorate.
(3) Since a minute pitch enlarged area is made in the central part with respect to the drying air direction after flux cleaning, pressure change of drying air does not occur, and defect countermeasures by underfill voids can be taken.
(4) The redesign man-hours of the package substrate is small, because it becomes the enlarged area creation of the chip central part without the increase in the number of bumps. Further, since the enlarged chip central portion is uniform and minute pitch, the stress distribution generated in the bump located at the connection portion of the semiconductor chip and the package substrate also becomes uniform. As a result, the flatness after chip mounting on the package substrate can also be ensured to the same extent as the conventional.

### Second Embodiment

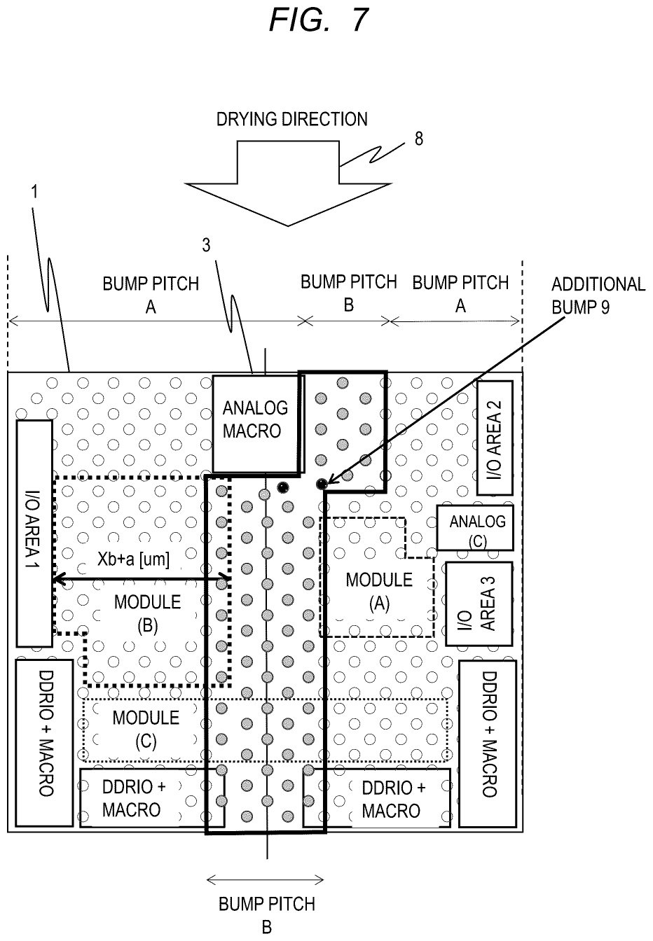

The bump arrangement method in the second embodiment will be described with reference to FIG. 7.

In the first embodiment, in the semiconductor chip 1, the area expansion method was described for the case where the analog macro or the like is not arranged in the central portion of the windward side of the drying direction. On the other hand, in the second embodiment, in the semiconductor chip 1, the central portion of the windward side of the dry air direction, the area enlargement method will be described for the case where there is an area where it is desired to keep the analog macro or the like bump pitch minimum. In this case, an enlarged area is created with a minute pitch on either the left or right side of the portion where the minimum pitch is required, or on both sides.

First, when area expansion is required, the chip size is first estimated according to the bump placement expansion flow as shown in FIG. 4. After the bump pitch B area is determined, how to place the bump pitch area in the central portion of the windward side of the drying direction of the semiconductor chip 1, it is determined according to the arrangement of the analog macro. Specifically, as shown in FIG. 7, placing the bump pitch B area in the central portion, for the vicinity of the area where the analog macro 3 is arranged to place the bump pitch B area so as to avoid the analog macro area.

Incidentally, it is desirable to add a bump to reduce the discontinuous portion so as to follow the minimum pitch rule when there is a space of more than 2 pitches (2A) in the boundary portion of the bump pitch A area and the bump pitch B area.

In the semiconductor chip, as a result of providing an enlarged area of different pitches so as to avoid it when there is an area that does not want to move such as an analog macro area, even if the discontinuous portion is generated on the windward side of the drying direction, the enlarged area of the different pitch as a whole since it is provided in the dry air direction, the inlet of the dry air direction of the flip-chip process is almost no pressure change of the dry air. Therefore, the water mark after drying does not occur, and it is possible to prevent the adhesion force decline and the occurrence of peeling after the underfill coating and curing.

Further, by expanding the bump arrangement on both sides or one side of the area where the bump pitch such as analog macro is desired to be kept to a minimum, it is possible to adjust the chip size without changing the bump arrangement such as analog macro or high-speed I/O.

### Third Embodiment

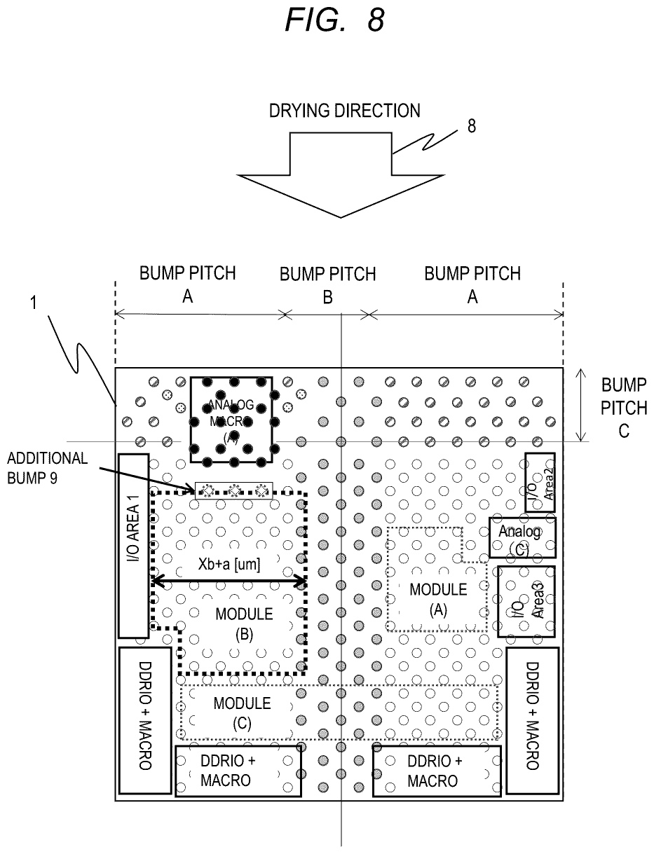

A third embodiment will be described with reference to FIG. 8.

In the first embodiment and the second embodiment, a method of expanding the size in the X direction of the semiconductor chip has been described. On the other hand, in the third embodiment, a description will be given of the area enlargement method in the case where it comes out necessary to enlarge the size not only in the X direction but also in the Y direction.

As shown in FIG. 8, first for size expansion in the X direction, in accordance with the bump arrangement enlargement flow as shown in FIG. 4, an estimate of the chip size to determine the arrangement of the bump pitch B area. At this time, as in the second embodiment, it may be arranged bump pitch B area in consideration of the area that does not want to move. Next, to provide a bump pitch C area in the Y direction, the bump pitch C area will be arranged from the windward side of the dry air direction.

If the space left on the lower side of the analog macro becomes 2 pitches or more, it is desirable to add bumps so that the bump pitch adheres to the minimum pitch rule in order not to make the space between bumps discontinuous as much as possible.

Since the adjustment of the area expansion is performed on the windward side in the dry air direction, it is possible to easily adjust the chip size not only in the X direction but also in the Y direction while maintaining the reliability in the flip-chip connection.

(Modified Embodiment)

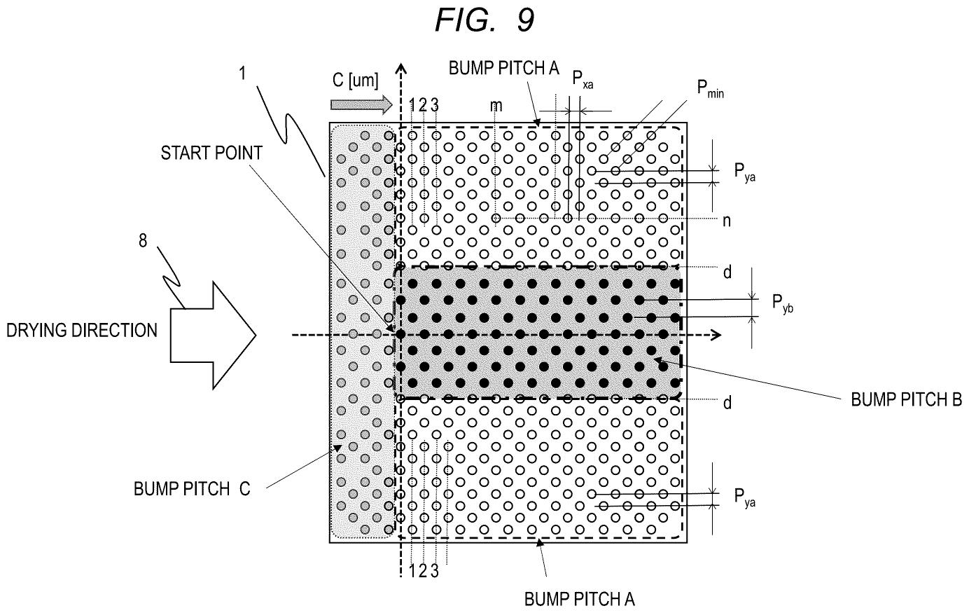

An example of bump arrangement when the left side is upwind in the drying direction is shown in FIG. 9.

If the dry air direction 8 becomes the left side of the semiconductor chip 1 will be described the case of providing a bump pitch B area and the bump pitch C area for area expansion. Even if there is a windward side in the drying direction on the left side, the area enlarged area is arranged in the same manner as when the upper side is a specific side in the first to third embodiments. At this time, the bump arrangement can be calculated as follows:
(1) Bump pitch A area: Assuming that the bump pitch is the process rule minimum pitch Pmin2=Pxa2+Pya2 (μm) (may be Pxa≠Pya)
(2) Bump pitch B area: Expands from the process rule to Pya(μm) from the center part of the left side in the vertical direction
(3) Bump pitch C area: There may be bump punching or discontinuous bump arrangement from the specified side to the X direction C(μm). Further, d, m, n is defined as an integer, when the left center portion of the bump pitch B area in FIG. 9 as a starting point, the m-th column, the n-th row of the bump coordinates (X, Y)
(4) Bump pitch A area: m≥0, |n|≥4|d|, (Pxa2+Pya2)=Pmin2), XAm=Pxa*m, YAn=Pyb*d+Pya×(n−d)
(5) Bump pitch B area: m≥0, |n|<|d|, XBm=Pxa*m, YBn=Pyb×n.

Since the bump pitch C area is bump-extractable or discontinuous pitch is allowed, the coordinates specific to each bump shall be used.

Although the invention made by the present inventor has been specifically described based on the embodiment, the present invention is not limited to the embodiment described above, and it is needless to say that various modifications can be made without departing from the gist thereof.

What is claimed is:

1. A semiconductor device comprising:
an electrode area disposed on a surface of a semiconductor chip, and a plurality of bumps arranged in a staggered lattice form in the electrode area,
wherein the electrode area has a first electrode area, a second electrode area and a third electrode area,
the second electrode area is disposed in a central portion of the electrode area,
a first bump pitch indicating the arrangement interval of a plurality of bumps disposed in the first electrode area and the third electrode area is different from the second bump pitch indicating the arrangement interval of a plurality of bumps disposed in the second electrode area.

2. The semiconductor device according to claim 1,
wherein the second bump pitch is wider than the first bump pitch.

3. The semiconductor device according to claim 1,
wherein the second electrode area is arranged along the direction of the dry air used in the drying step in the manufacturing process of the semiconductor device.

4. A semiconductor device comprising:
an electrode area disposed on a surface of a semiconductor chip, and a plurality of bumps arranged in a staggered lattice form in the electrode area,
wherein the electrode area has a first electrode area, a second electrode area, a third electrode area and a fourth electrode area,
the center line of the fourth electrode area and the center line of the second electrode area is disposed in the central portion of the electrode area so as not to overlap each other,
a first bump pitch indicating the arrangement interval of a plurality of bumps disposed in the first electrode area and the third electrode area is different from the second bump pitch indicating the arrangement interval of a plurality of bumps disposed in the second electrode area and the fourth electrode area.

5. The semiconductor device of claim 4,
wherein the second bump pitch is wider than the first bump pitch.

6. The semiconductor device according to claim 4,
wherein the second electrode area and the fourth electrode area are arranged along the direction of the dry air used in the drying step in the manufacturing process of the semiconductor device.

7. A semiconductor device comprising:
an electrode area disposed on a surface of a semiconductor chip, and a plurality of bumps arranged in a staggered lattice form in the electrode area,
wherein the electrode area has a first electrode area, a second electrode area, a third electrode area and a fourth electrode area,
the second electrode area is disposed in a central portion of the electrode area,
the fourth electrode area is disposed perpendicular to the first electrode area and the second electrode area and the third electrode area,
a first bump pitch indicating the arrangement interval of a plurality of bumps disposed in the first electrode area and the third electrode area is different from the second bump pitch indicating the arrangement interval of a plurality of bumps disposed in the second electrode area and the fourth electrode area.

8. The semiconductor device of claim 7,
wherein the second bump pitch is wider than the first bump pitch.

9. The semiconductor device according to claim 8,
wherein the second electrode area is disposed along the direction of the dry air used in the drying step in the manufacturing process of the semiconductor device,
the fourth electrode area is disposed perpendicular to the direction of the dry air.

10. A method of manufacturing a semiconductor device:
the semiconductor device has an electrode area disposed on a surface of a semiconductor chip, and a plurality of bumps arranged in a staggered lattice form in the electrode area,
wherein the electrode area has a first electrode area, a second electrode area and a third electrode area,
the second electrode area is disposed in a central portion of the electrode area,
a first bump pitch indicating the arrangement interval of a plurality of bumps disposed in the first electrode area and the third electrode area is different from the second bump pitch indicating the arrangement interval of a plurality of bumps disposed in the second electrode area.

11. A method of manufacturing a semiconductor device:
the semiconductor device has an electrode area disposed on a surface of a semiconductor chip, and a plurality of bumps arranged in a staggered lattice form in the electrode area,
wherein the electrode area has a first electrode area, a second electrode area, a third electrode area and a fourth electrode area,
the center line of the fourth electrode area and the center line of the second electrode area is disposed in the central portion of the electrode area so as not to overlap each other,
a first bump pitch indicating the arrangement interval of a plurality of bumps disposed in the first electrode area and the third electrode area is different from the second bump pitch indicating the arrangement interval of a plurality of bumps disposed in the second electrode area and the fourth electrode area.

12. A method of manufacturing a semiconductor device:
the semiconductor device has an electrode area disposed on a surface of a semiconductor chip, and a plurality of bumps arranged in a staggered lattice form in the electrode area,
wherein the electrode area has a first electrode area, a second electrode area, a third electrode area and a fourth electrode area,
the second electrode area is disposed in a central portion of the electrode area,
the fourth electrode area is disposed perpendicular to the first electrode area and the second electrode area and the third electrode area,
a first bump pitch indicating the arrangement interval of a plurality of bumps disposed in the first electrode area and the third electrode area is different from the second bump pitch indicating the arrangement interval of a plurality of bumps disposed in the second electrode area and the fourth electrode area.
